(19) United States
(12) Patent Application Publication
(10) Pub. No.: US 2008/0100204 A1
(43) Pub. Date: May 1, 2008

(54) MASK AND DEPOSITION APPARATUS USING THE SAME

(75) Inventor: Tae Seung Kim, Suwon-si (KR)

Correspondence Address: KNOBBE MARTENS OLSON & BEAR LLP, 2040 MAIN STREET, FOURTEENTH FLOOR, IRVINE, CA, 92614, US

(73) Assignee: Samsung SDI Co., Ltd., Suwon-si (KR)

(21) Appl. No.: 11/743,600

(22) Filed: May 2, 2007

(30) Foreign Application Priority Data
Oct. 27, 2006 (KR) 10-2006-0105109

(51) Int. Cl. H01J 1/62

(52) U.S. Cl. 313/504; 118/213; 118/721

(57) ABSTRACT

A mask and a deposition apparatus using the same are disclosed. One embodiment of the mask is used for depositing a thin film on the substrate having a plurality of sub-pixel regions. The mask includes a first region having a plurality of the first openings, each of which corresponds to one of the plurality of sub-pixel regions. The mask also includes second regions having a plurality of the second openings, each of which corresponds to at least two of the plurality of the sub-pixel regions. The second regions are positioned on both sides of the first region.

### CROSS-REFERENCE TO RELATED APPLICATIONS

This application claims the benefit of Korean Patent Application No. 2006-0105109, filed on Oct. 27, 2006, in the Korean Intellectual Property Office, the disclosure of which is incorporated herein by reference.

### BACKGROUND

1. Field

The present invention relates to a mask and a deposition apparatus using the same, and more particularly, to a mask and a deposition apparatus using the same for forming a thin film on a substrate.

2. Description of the Related Technology

Generally, an organic light emitting diode used for a flat panel display device includes two electrodes opposing each other. The diode also includes an organic layer interposed between the two electrodes. The organic layer includes an emission layer, and optionally at least one of a hole injection layer, a hole transport layer, an electron transport layer, and an electron injection layer, etc. These layers are thin films made of organic materials. In manufacturing an organic light emitting diode, organic thin films such as an emission layer, a hole injection layer, a hole transport layer, an electron transport layer, or an electron injection layer, etc. may be formed by a deposition method using a deposition apparatus.

### SUMMARY OF CERTAIN INVENTIVE ASPECTS

One embodiment is a mask for use in depositing a thin film on a partially fabricated display device. The mask comprises a first region including an array of first openings, each of the first openings having a first length measured along a first axis, the first region having an edge extending along a second axis substantially perpendicular to the first axis; and a second region adjoining the edge of the first region, the second region including an array of second openings, each of the second openings having a second length measured along the first axis, the second length being at least twice the length of the first length, wherein the second openings are substantially aligned with the first openings along the first axis.

Each of the first openings may have a substantially square or rectangular shape. Each of the second openings may have a stripe shape extending along the first axis. The first openings may be arranged in a matrix form. Each of the first openings may have a first width measured along the second axis, and each of the second openings may have a second width measured along the second axis. The first width may be substantially the same as the second width. The second openings may be substantially aligned with one another along the second axis.

Each of the first openings may have a first size, and each of the second openings may have a second size. The second size may be at least twice as large as the first size. The ratio of the areas of the first region and the second region may be about 4:3.

The mask may further comprise a third region adjoining the first region on the opposite side from the second region, the third region including an array of third openings, each of the third openings having a third length measured along the first axis, the third length being at least twice the length of the first length, wherein the third openings are substantially aligned with the first openings along the first axis. Each of the third openings may have a stripe shape.

The mask may further comprise a third region adjoining the second region on the opposite side from the first region, the third region including an array of third openings, each of the third openings having a third length measured along the first axis, the third length being substantially the same as the first length, wherein the third openings are substantially aligned with the second openings along the first axis. Each of the third openings may have a substantially square or rectangular shape.

Another embodiment is a deposition apparatus for forming a thin film on a partially fabricated display device. The apparatus comprises a chamber; a substrate supporter positioned within the chamber; at least two deposition sources facing the substrate supporter, the deposition sources being spaced apart from one another, the deposition sources being configured to vaporize a deposition material toward the substrate supporter; and the mask described above, the mask being positioned between the substrate holder and the deposition sources, wherein the deposition sources are substantially aligned with one another along the first axis.

Yet another embodiment is a method of making a display device. The method comprises: placing a partially fabricated display device in the deposition apparatus described above, such that the display device is supported by the substrate holder while being interposed between the substrate holder and the mask, the display device having a surface facing the mask; and vaporizing a deposition material from the deposition sources such that the deposition material passes through the mask, thereby selectively reaching portions of the surface of the display device.

The display device may be an organic light emitting display device. The deposition material may be an organic light-emitting material.

Another embodiment is an organic light emitting display device which comprises: a substrate having a pixel region, the pixel region having a first region and a second region adjoining the first region in a first direction; an array of first organic layers formed over the first region of the substrate, each of the first organic layers having a first length measured along a first axis extending in the first direction; and an array of second organic layers formed over the second region of the substrate, each of the second organic layers having a second length measured along the first axis, the second length being at least twice the length of the first length, wherein the second organic layers are substantially aligned with the first organic layers along the first axis.

The first and second organic layers may be formed of an organic light-emitting material. The substrate may further comprise a third region adjoining the first region on the opposite side from the second region, wherein the device further comprises an array of third organic layers, each of the third organic layers having a third length measured along the first axis, the third length being at least twice longer than the first length, and wherein the third organic layers are substantially aligned with the first organic layers along the first axis. The substrate may further comprise a third region adjoining the second region on the opposite side from the first region, wherein the device further comprises an array of third organic layers, each of the third organic layers having a third length measured along the first axis, the third length being substantially the same as the first length, and wherein the third organic layers are substantially aligned with the second organic layers along the first axis.

Another embodiment is a mask to deposit a thin film on a substrate including a plurality of sub-pixel regions and positioned on front of the substrate. The mask comprises a first region having a plurality of the first openings which corresponds to each region of a plurality of the sub-pixel regions, and a second region having a plurality of the second openings which corresponds to at least two sub-pixel regions of a plurality of the sub-pixel regions and positioned on the both sides of the first region having a plurality of the first openings.

Yet another embodiment is a deposition apparatus which comprises a chamber, a supporter supporting a substrate including a plurality of sub-pixel regions which is put into the chamber, at least two deposition sources to supply deposition materials onto the substrate, and a mask which comprises a first region having a plurality of the first openings which corresponds to each region of a plurality of the sub-pixel regions and a second region having a plurality of the second openings which corresponds to at least two sub-pixel regions of a plurality of the sub-pixel regions and positioned on the both sides of the first region having a plurality of the first openings.

Yet another embodiment is an organic light emitting display device having a plurality of the sub-pixels comprising a first electrode, a second electrode and an emission layer arranged between the first electrode and the second electrode comprises a plurality of first patterns respectively formed on each region of a plurality of the sub-pixels and a plurality of second patterns successively formed on at least two sub-pixels of a plurality of the sub-pixels and arranged on the both sides of the first patterns.

### BRIEF DESCRIPTION OF THE DRAWINGS

FIG. 1 is a perspective view illustrating a conventional deposition apparatus for forming a thin film on a substrate.

FIG. 2 illustrates a conventional mask used for depositing a thin film.

FIG. 3 is a micrograph, taken with a scanning electron microscope, of a thin film pattern formed on a substrate, using a conventional mask.

FIG. 4 is an exploded perspective view of a mask according to one embodiment.

FIG. 5 is a cross-sectional view illustrating a deposition apparatus for forming a thin film on a substrate according to another embodiment.

FIG. 6 is a perspective view of an organic light emitting display device according to one embodiment.

FIG. 7 is a cross-sectional of the device of FIG. 6, taken along the line I-I′ in FIG. 6.

FIG. 8 is a cross-sectional view of the device of FIG. 6, taken along the line II-II′ in FIG. 6.

FIG. 9 is a cross-sectional view of the device of FIG. 6, taken along line III-III′ in FIG. 6.

### DETAILED DESCRIPTION OF CERTAIN INVENTIVE EMBODIMENTS

In making a device having a large size substrate, a multiple deposition method to deposit a thin film using a plurality of deposition sources can be used to form an organic material layer. Such a method provides fine step coverage and uniformity on a substrate.

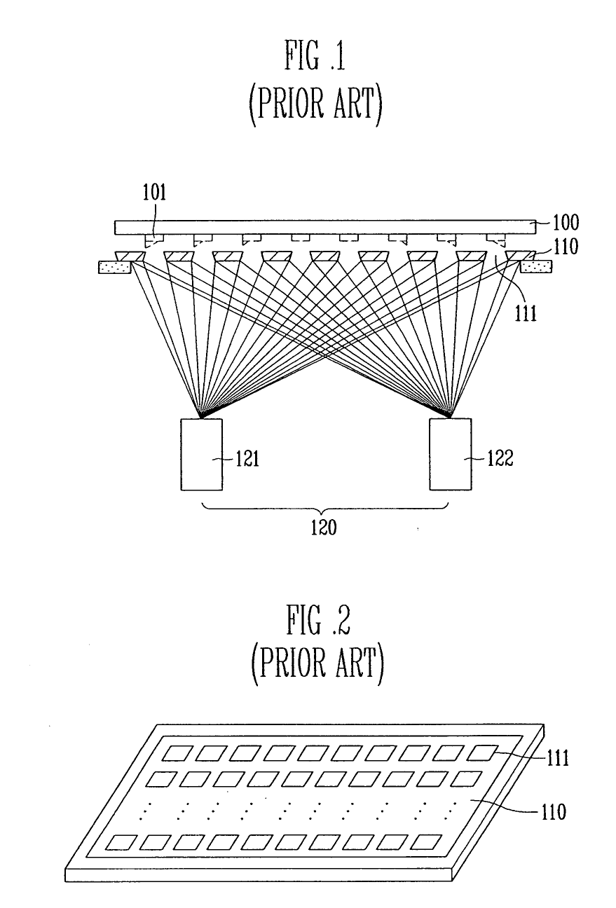

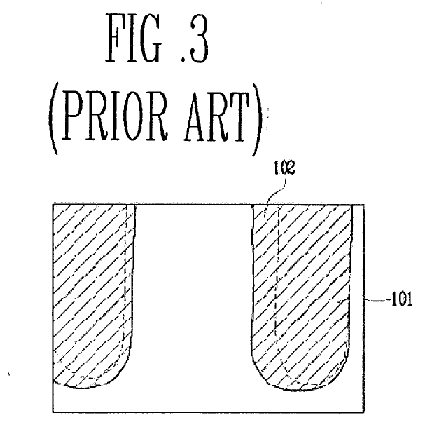

FIG. 1 illustrates a conventional mask used for forming a thin film on a substrate. FIG. 2 is a perspective view illustrating a conventional deposition apparatus for forming a thin film on a substrate. FIG. 3 is a micrograph illustrating a thin film pattern formed on a substrate using the conventional mask.

Referring to FIGS. 1 to 3, a chamber (not shown) includes a substrate 100 on which a thin film 101 is to be formed, a mask 110 positioned in front of the substrate 100, and at least two deposition sources 120 to provide material for the thin film 101.

In order to form the thin film 101 on the substrate 100, deposition materials are vaporized by heating deposition sources containing deposition materials. The deposition materials evaporated from deposition sources 120 are deposited on the substrate 100 through openings 111 of the mask 110. The openings 111 may be dot-shaped. Thin film patterns 101 corresponding to the dot shaped openings 111 are formed on the substrate 100.

However, portions of the materials which are directed to peripheries of the substrate 100 may not sufficiently reach the substrate 100, which may cause a non-uniform thickness at the peripheries of the substrate. Such portions have a small incident angle to the mask 110. Thus, the portions, while traveling toward the substrate 100, may be blocked by the mask 110, and may not reach the substrate 100 in a sufficient amount to form a layer of a uniform thickness. Thus, the peripheries of the substrate 100 may have sawtooth-shaped layers, as shown in FIG. 1.

As shown in FIG. 3, a thin film pattern corresponding to the shape of the openings 111 may not be formed on the substrate 100. The thin film 101 may not be uniform. In FIG. 3, a portion 102 of the film 101 is thinner than another portion 101 thereof. These problems occur since the deposition materials are properly deposited on some regions, but not on other regions as described above.

A method forming a thin film on a substrate using a mask including stripe-shaped openings is proposed to provide a thin film having a uniform thickness. However, the mask including the stripe-shaped openings tends to bend down in its middle region due to external tensile force and its own weight. Therefore, a uniform thin film cannot be formed on a substrate, causing a so-called shadow phenomenon, for example, at the portion 102 of FIG. 3.

In one embodiment, a mask has a central region and two side regions. The mask includes a plurality of first openings in the central region and a plurality of second openings in the side regions. The second openings have a size at least twice as large as the first openings.

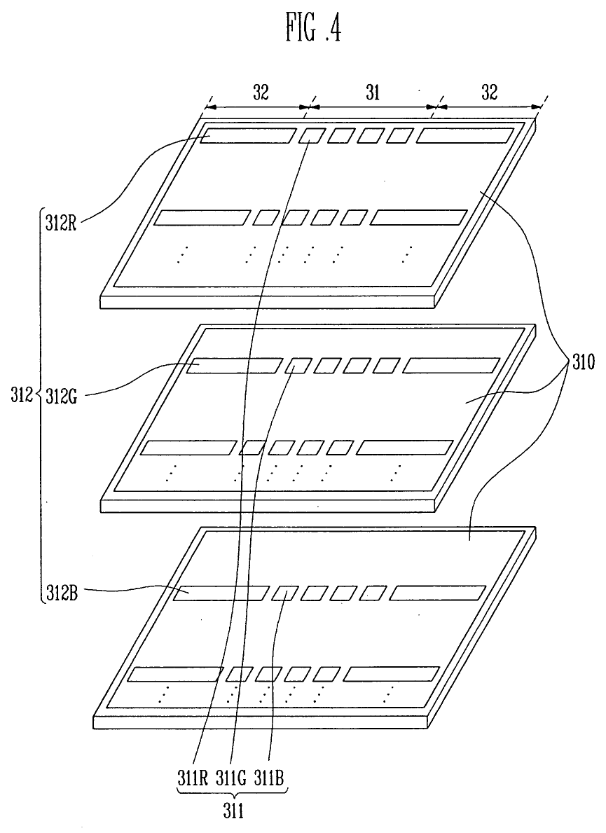

FIG. 4 is an exploded perspective view illustrating a mask used for depositing a thin film on a substrate, according to one embodiment. In one embodiment, an organic light emitting display device may be made using the mask. A substrate (not shown) on which a thin film is to be formed is first provided. The substrate may include a plurality of sub-pixel regions. A mask 310 may be positioned to face a surface of the substrate. The illustrated mask 310 includes a first region 31 and two second regions 32. The first region 31 includes a plurality of first openings 311, each corresponding to one of the plurality of sub-pixel regions. The second regions 32 include a plurality of second openings 312, each corresponding to at least two of the plurality of sub-pixel regions. The second regions 32 are positioned on both sides of the first region 31.

In the illustrated embodiment, the first region 31 includes a plurality of dot-shaped first openings in a matrix form. The plurality of dot-shaped first openings 311 correspond to sub-pixel regions (sub-pixel: R, G, B) in the emission region of the substrate.

The sub-pixel regions described in the embodiment are defined by a pixel definition film formed over the substrate. The pixel definition layer has a plurality of openings. Each opening defines one of the sub-pixel regions.

In the illustrated mask, a plurality of first red openings 311R are arranged to correspond to red sub-pixel regions to be formed on the substrate. A plurality of first green openings 311 G are arranged to correspond to green sub-pixel regions to be formed on the substrate. A plurality of first blue openings 311B are arranged to correspond to blue sub-pixel regions to be formed on the substrate.

In addition, the second openings 312 are formed on the second regions 32 on both sides of the first region 31. The second openings 312 are aligned with the first openings 311. The second openings 312 have a stripe shape. The second openings 312 have a size at least twice as large as that of a sub-pixel region on the substrate. The second openings 312 may have red, green, and blue openings 312R, 312G, 312B. Each of the second red openings 312R may have a size at least twice as large as that of a red sub-pixel region on the substrate. Each of the second green openings 312G may have a size at least twice as large as that of a green sub-pixel region on the substrate. Each of the second blue openings 312B may have a size at least twice as large as that of a blue sub-pixel region on the substrate.

The first openings 311 and the second openings 312 may be formed by an etching method using, for example, photolithography, an electro-forming method using photolithography and electrolysis, and a laser cutting method. In one embodiment, the ratio of the areas of the first region 31 and the second region 32 is about 4:3.

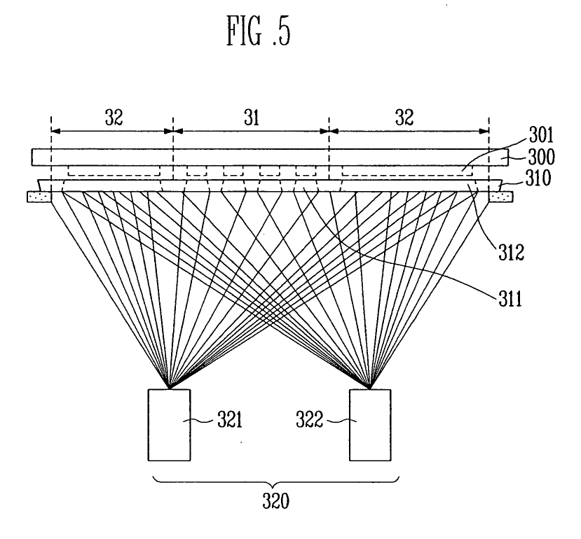

FIG. 5 is a cross-sectional view illustrating a deposition apparatus for forming a thin film on a substrate according to one embodiment. Referring to FIG. 5, the deposition apparatus includes a chamber (not shown), a supporter (not shown) for supporting or holding a substrate 300, at least two deposition sources 320 for supplying deposition materials on the substrate 300, and a mask 310.

The deposition sources 320 are positioned at the lower side of the chamber. The deposition sources include deposition materials and a heater. The heater is configured to vaporize the deposition materials such that the materials can be deposited on the substrate 300. The deposition source 320 can move horizontally or vertically, using a moving device (not shown) installed in the chamber. The illustrated deposition sources 320 include a first deposition source 321 and a second deposition source 322. This configuration can simultaneously provide the deposition materials on substantially the entire surface of the substrate 300. It will be appreciated that various numbers of deposition sources can be used, depending on the size of the substrate.

The substrate supporter is configured to support the substrate 300. The supporter is provided at the upper side of the chamber. The supporter opposes the deposition source provided at the lower side of the chamber.

The mask 310 includes a first region 31 having a plurality of the first openings 311, and two second regions 32 having a plurality of second openings 312. The first region 31 is interposed between the two second regions 32. In one embodiment, the first region 31 and one of the second regions 32 have an area ratio of about 4:3. The second openings 312 may have a size at least twice as large as that of the first openings 311. The first openings 311 and the second openings 312 together determine a pattern of a thin film which will be formed on the substrate 300. The mask 310 is positioned between the substrate 300 and the deposition sources 320. In certain embodiments, the mask 310 can be fixed on the substrate 300 by welding or by an adhesive.

The first openings 311 are dot-shaped and arranged in a matrix form. Each of the openings 311 has a size corresponding to that of one of sub-pixel regions (sub-pixel: R, G, B) of the substrate 300. For example, the mask 310 may have first openings 311 corresponding to a plurality of red sub-pixel regions of the substrate 300. For example, a plurality of red thin films 301 corresponding to the red sub-pixel regions (R) can be formed on the substrate 300.

The second openings 312 are provided on both sides of the first region 31. The second openings 312 may have a stripe shape. The stripe-shaped second openings 312 may a size at least twice as large as a sub-pixel region (e.g., sub-pixel: R). Accordingly, continuous thin films 301 having a size corresponding to two red sub-pixel regions (R, R) can be formed on the substrate 300.

In the illustrated embodiment, the large-sized second openings 312 are formed in the second regions 32, opening the peripheries of the substrate. Therefore, even when the depositing angle of the deposition material evaporated from the first deposition source 321 or the second deposition source 322 is small, it is possible to prevent interference due to the mask pattern. The configuration of the mask 310 can provide high resolution display devices since a thin film can be formed on a substrate without a shadow phenomenon.

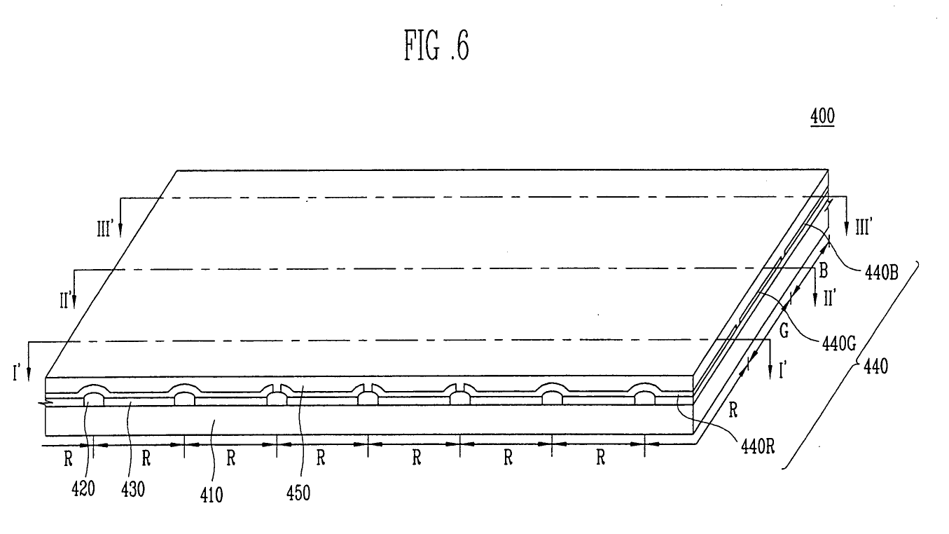

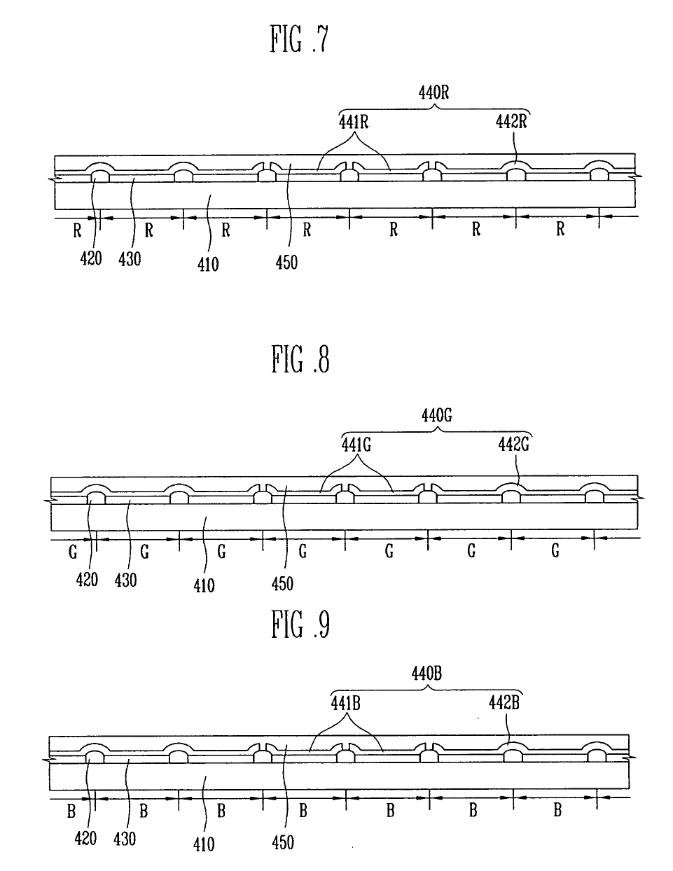

FIG. 6 is a perspective view of an organic light emitting display device according to one embodiment. FIG. 7 is a cross-sectional view of the display device, taken along the line I-I′ in FIG. 6. FIG. 8 is a cross-sectional view of the display device, taken along the line II-II′ in FIG. 6. FIG. 9 is a cross-sectional view of the display device, taken along the line III-III′ in FIG. 6.

Referring to FIG. 6 to FIG. 9, an organic light emitting display device 400 has a plurality of sub-pixels formed over a substrate 410. Each sub-pixel includes a first electrode layer, a second electrode layer 430, 450 and an emission layer 440 interposed between the first electrode layer and the second electrode layer 430, 450. Referring to FIG. 7, the display device 400 includes a plurality of first patterns 441 of a first size and a plurality of second patterns 442 of a second size. Each of the first patterns 441 forms one of sub-pixels of the display device. The second patterns 442 may have a size at least twice as large as that of a sub-pixel. The second patterns 442 are positioned on both sides of the first patterns 441. A plurality of red, green and blue sub-pixels (R sub-pixel, G sub-pixel, B sub-pixel) formed of an emission layer 440 are positioned between the first electrode layer and the second electrode layer 430, 450.

The first electrode layer 430 may be formed on the substrate by depositing and patterning a conductive layer. The first electrode layer may be either a transparent electrode and a reflective electrode. The transparent electrode can be formed of ITO, IZO, ZnO, or In₂O₃. The reflective electrode can be formed of Ag, Mg, Al, Pt, Pd, Au, Ni, Nd, Ir, Cr, or a combination thereof. The reflective electrode may further include a layer formed of ITO, IZn, ZnO, or In₂O₃. A pixel definition film 420 is formed on the first electrode layer 430. The pixel definition film 420 has openings at least partially exposing the first electrode layer.

A red emission layer 440R may have first red patterns 441R and second red patterns 442R in red sub-pixel regions (R). A green emission layer 440G may have first green patterns 441G and second green patterns 442G in green sub-pixel regions (G).

The red emission layer 440R may have a plurality of first red patterns 441R which form red sub-pixels. The second red patterns 442R are arranged on both sides of the first red pattern 441R. The second red patterns 442R may have a size at least twice as large as that of a red sub-pixel region (R). Similarly, the green and blue emission layers 440G, 440B may have green and blue patterns 441G, 441B, 442G, 442B, which form green and blue sub-pixels, respectively.

The second electrode layer 450 is formed on the red, green and blue emission layers 440R, 440G, 440B. The second electrode layer 450 can be either a transparent electrode or a reflective electrode. The transparent electrode can be formed by first depositing a low work function metal such as Li, Ca, LiF/Ca, LiF/Al, Al, Ag, Mg or a combination thereof on the emission layer 440, and then forming another layer with ITO, IZO, ZnO or In₂O₃ on the metal. The reflective electrode can be formed of Li, Ca, LiF/Ca, LiF/Al, Al, Ag, Mg or a combination thereof.

The embodiments described above can provide uniform thin films on a substrate. Further, the uniform the thin films can provide a display device which is capable of displaying high quality pictures with a high resolution.

Although a few embodiments of the invention have been shown and described, it would be appreciated by those skilled in the art that changes might be made in this embodiment without departing from the principles and spirit of the invention, the scope of which is defined in the claims and their equivalents.

What is claimed is:

1. A mask for use in depositing a thin film on a partially fabricated display device, the mask comprising:
a first region including an array of first openings, each of the first openings having a first length measured along a first axis, the first region having an edge extending along a second axis substantially perpendicular to the first axis; and
a second region adjoining the edge of the first region, the second region including an array of second openings, each of the second openings having a second length measured along the first axis, the second length being at least twice the length of the first length, wherein the second openings are substantially aligned with the first openings along the first axis.

2. The mask of claim 1, wherein each of the first openings has a substantially square or rectangular shape.

3. The mask of claim 1, wherein each of the second openings has a stripe shape extending along the first axis.

4. The mask of claim 1, wherein the first openings are arranged in a matrix form.

5. The mask of claim 1, wherein each of the first openings has a first width measured along the second axis, wherein each of the second openings has a second width measured along the second axis, and wherein the first width is substantially the same as the second width.

6. The mask of claim 5, wherein the second openings are substantially aligned with one another along the second axis.

7. The mask of claim 1, wherein each of the first openings has a first size, wherein each of the second openings has a second size, and wherein the second size is at least twice as large as the first size.

8. The mask of claim 1, wherein the ratio of the areas of the first region and the second region is about 4:3.

9. The mask of claim 1, further comprising a third region adjoining the first region on the opposite side from the second region, the third region including an array of third openings, each of the third openings having a third length measured along the first axis, the third length being at least twice the length of the first length, wherein the third openings are substantially aligned with the first openings along the first axis.

10. The mask of claim 9, wherein each of the third openings has a stripe shape.

11. The mask of claim 1, further comprising a third region adjoining the second region on the opposite side from the first region, the third region including an array of third openings, each of the third openings having a third length measured along the first axis, the third length being substantially the same as the first length, wherein the third openings are substantially aligned with the second openings along the first axis.

12. The mask of claim 11, wherein each of the third openings has a substantially square or rectangular shape.

13. A deposition apparatus for forming a thin film on a partially fabricated display device, comprising:
a chamber;
a substrate supporter positioned within the chamber;
at least two deposition sources facing the substrate supporter, the deposition sources being spaced apart from one another, the deposition sources being configured to vaporize a deposition material toward the substrate supporter; and
the mask of claim 1, the mask being positioned between the substrate holder and the deposition sources,
wherein the deposition sources are substantially aligned with one another along the first axis.

14. A method of making a display device, the method comprising:
placing a partially fabricated display device in the deposition apparatus of claim 13, such that the display device is supported by the substrate holder while being interposed between the substrate holder and the mask, the display device having a surface facing the mask; and
vaporizing a deposition material from the deposition sources such that the deposition material passes through the mask, thereby selectively reaching portions of the surface of the display device.

15. The method of claim 14, wherein the display device is an organic light emitting display device.

16. The method of claim 15, wherein the deposition material is an organic light-emitting material.

17. An organic light emitting display device, comprising:
a substrate having a pixel region, the pixel region having a first region and a second region adjoining the first region in a first direction;
an array of first organic layers formed over the first region of the substrate, each of the first organic layers having a first length measured along a first axis extending in the first direction; and
an array of second organic layers formed over the second region of the substrate, each of the second organic layers having a second length measured along the first axis, the second length being at least twice the length of the first length, wherein the second organic layers are substantially aligned with the first organic layers along the first axis.

18. The device of claim 17, wherein the first and second organic layers are formed of an organic light-emitting material.

19. The device of claim 17, wherein the substrate further comprises a third region adjoining the first region on the opposite side from the second region, wherein the device further comprises an array of third organic layers, each of the third organic layers having a third length measured along the first axis, the third length being at least twice longer than the first length, and wherein the third organic layers are substantially aligned with the first organic layers along the first axis.

20. The device of claim 17, wherein the substrate further comprises a third region adjoining the second region on the opposite side from the first region, wherein the device further comprises an array of third organic layers, each of the third organic layers having a third length measured along the first axis, the third length being substantially the same as the first length, and wherein the third organic layers are substantially aligned with the second organic layers along the first axis.
